(19) United States
(12) Patent Application Publication
(10) Pub. No.: US 2026/0190441 A1
(43) Pub. Date: Jul. 2, 2026

(54) High-Voltage Process for Forming an Integrated Structure of MOS Device

(71) Applicant: Shanghai Huali Integrated Circuit Corporation, Shanghai (CN)

(72) Inventor: Xiaoliang Tang, Shanghai (CN)

(73) Assignee: Shanghai Huali Integrated Circuit Corporation, Shanghai (CN)

(21) Appl. No.: 19/299,466

(22) Filed: Aug. 14, 2025

(30) Foreign Application Priority Data
Jan. 2, 2025 (CN) 202510008738.0

(51) Int. Cl. H10D 84/01; H01L 21/311; H10D 30/01; H10D 64/66; H10D 64/68; H10D 84/83

(52) U.S. Cl. CPC H10D 84/0144; H10D 30/027; H10D 64/675; H10D 64/685; H10D 64/691; H10D 64/693; H10D 84/013; H10D 84/0142; H10D 84/0147; H10P 50/283; H10D 64/661; H10D 84/83138; H10D 84/8314

(57) ABSTRACT

The present invention discloses a high-voltage process for forming an integrated structure of MOS device. After depositing gate polysilicon and the first mask layer, the medium-voltage device gate structure region pattern is first defined by the first gate mask. By using a separate mask, the medium-voltage device gate structure is etched to ensure removal of the gate dielectric layer outside the medium-voltage device gate structure region, thereby exposing the top surface of silicon substrate. After depositing the second spacer material layer, a blank etch over the target area forms normal sidewall spacers of high-voltage device gate structure and thickens the sidewall spacers of medium-voltage device, thereby saving one mask for sidewall spacer formation.

### CROSS-REFERENCE TO RELATED APPLICATIONS

This application claims priority to Chinese patent application No. 2025100087380, filed on Jan. 2, 2025, the disclosure of which is incorporated herein by reference in its entirety.

### TECHNICAL FIELD

The present invention belongs to the semiconductor manufacturing technology, and in particular to a high-voltage process for forming an integrated structure of MOS device.

### BACKGROUND

The HV (High Voltage) processes are primarily applied in manufacturing of display driver chips. The display driver chip comprises low-voltage MOS devices, medium-voltage MOS devices and high-voltage MOS devices. The low-voltage MOS devices are required to operate at low voltages (several tenths of a volt to just over one volt) and support high-speed performance. The medium-voltage MOS devices, which operate at 6 V to 10 V, are used for the brightness adjustment of the display's light-emitting units. The high-voltage MOS devices, which operates at 20 V to 40 V, are primarily used to drive the display. Compared with 28 HK (28 nm High-K) process, the 28 HV (28 nm High-Voltage) process involves more steps and requires several additional masks.

In existing high-voltage process for forming an integrated structure of MOS devices, during gate polysilicon etching step, relatively thick gate dielectric layer of medium-voltage MOS device may result in residual gate dielectric remaining on active region of the silicon substrate. After performing gate polysilicon etching process, at least 2 additional masks are required: one for second spacer etching and another for interfacial oxide removal (IOR etch) in the medium-voltage MOS device formation region.

### BRIEF SUMMARY

The present invention discloses a high-voltage process for forming integrated structure of MOS device, which comprises following steps:
S1: performing an active region process on a silicon substrate 100, such that silicon substrate 100 is divided by shallow trench isolation 104 into a high-voltage device region 101 and a medium-voltage device region 102;
S2: forming the gate dielectric layers 105 on silicon substrate 100 in high-voltage device region 101 as well as medium-voltage device region 102 respectively, wherein the top surfaces of the gate dielectric layer 105 are flush with the top surface of the shallow trench isolation 104, and gate dielectric layer 105 in the high-voltage device region 101 is thicker than that in the medium-voltage device region 102;
S3: sequentially forming a high-k dielectric layer 106, a gate polysilicon layer 107 and a first mask layer 108 over the gate dielectric layers 105;
S4: defining a gate structure region in the medium-voltage device region 102 using a first gate mask, and etching away portions of the first mask layer 108, the gate polysilicon layer 107, the high-k dielectric layer 106, and the gate dielectric layer 105 located outside the medium-voltage gate structure region, stopping at the top surface of the silicon substrate 100, thereby exposing top surface of silicon substrate 100 outside medium-voltage gate structure region, retaining the stack within the medium-voltage gate structure region comprising gate dielectric layer 105, high-k dielectric layer 106, gate polysilicon layer 107 and first mask layer 108 in sequence, which together form medium-voltage gate structure, while retaining a stack of gate dielectric layer 105, high-k dielectric layer 106, gate polysilicon layer 107 and first mask layer 108 in sequence in high-voltage device region 101; and removing photoresist thereafter;
S5: depositing a first spacer material layer 109;
S6: performing wet etching to retain the first spacer material layer 109 only on side surfaces of stack comprising first mask layer 108, gate polysilicon layer 107, high-k dielectric layer 106 and gate dielectric layer 105, and removing the rest, thereby forming the sidewall spacer of the medium-voltage gate structure;
S7: defining the high-voltage gate structure region in the high-voltage device region 101 using a second gate mask, and etching away the portions of the first mask layer 108, the gate polysilicon layer 107 and the high-k dielectric layer 106 in high-voltage device region 101 outside high-voltage gate structure region, stopping at top surface of the gate dielectric layer 105, retaining the stack within high-voltage gate structure region comprising the high-k dielectric layer 106, gate polysilicon layer 107 and the first mask layer 108 in sequence over gate dielectric layer 105 to form high-voltage gate structure, while retaining medium-voltage gate structure in medium-voltage gate structure region; and removing photoresist thereafter;
S8: depositing a second spacer material layer 110;
S9: performing wet etching to remove the second spacer material layer 110 except for portions on side surfaces of medium-voltage gate structure and high-voltage gate structure, thereby exposing top surface of silicon substrate 100 outside medium-voltage gate structure region in medium-voltage device region 102, retaining the portions of second spacer material layer 110 on the side surfaces of the medium-voltage as well as high-voltage gate structures forming sidewall spacer of the high-voltage gate structure; and making the sidewall spacers of medium-voltage gate structure the first spacer material layer as well as the second spacer material layer 110 stacked laterally;
S10: performing subsequent processes.

Preferably, step S10 comprises performing source/drain ion implantation to form a source/drain region of the medium-voltage device and a source/drain region of high-voltage device, wherein
source/drain region of the high-voltage device is self-aligned with sidewall spacers of the high-voltage gate structure; and wherein
source/drain region of the medium-voltage device is self-aligned with the sidewall spacers of the medium-voltage gate structure.

Preferably, in step S1, silicon substrate 100 is divided by shallow trench isolation 104 into a high-voltage device region 101, a medium-voltage device region 102 as well as a low-voltage device region 103, wherein
in step S2, gate dielectric layer 105 is further formed on the silicon substrate 100 in medium-voltage device region 102, and each gate dielectric layer 105 has a top surface that is flush with top surface of the shallow trench isolation 104; the thickness of the gate dielectric layer in high-voltage device region 101 is greater than that in medium-voltage device region 102, and the thickness of the gate dielectric layer in the medium-voltage device region 102 is greater than that in the low-voltage device region 103, wherein
in step S4, the sequentially stacked first mask layer 108, gate polysilicon gate layer 107, high-k dielectric layer 106 and gate dielectric layer 105 in the low-voltage device region 103 are retained, wherein
in step S7, a second gate mask is used to define high-voltage gate structure region in the high-voltage device region 101 and low-voltage gate structure region in the low-voltage device region 103; etching is performed to remove first mask layer 108, gate polysilicon layer 107 and high-k dielectric layer 106 in high-voltage device region 101 outside high-voltage gate structure region, stopping at top surface of the gate dielectric layer 105; etching is also performed to remove the first mask layer 108, the gate polysilicon layer 107 and the high-k dielectric layer 106 in the low-voltage device region 103 outside low-voltage gate structure region, stopping at top surface of the gate dielectric layer 105, wherein the high-k dielectric layer 106, gate polysilicon layer 107 and first mask layer 108 sequentially stacked on gate dielectric layer 105 in the high-voltage gate structure region and low-voltage gate structure region are retained as high-voltage gate structure and low-voltage gate structure respectively; medium-voltage gate structure in medium-voltage gate structure region is also retained; and the photoresist is removed thereafter, wherein
in step S9, wet etching is performed to remove the second spacer material layer 110 outside side surfaces of medium-voltage gate structure, low-voltage gate structure as well as high-voltage gate structure, thereby exposing the top surface of the silicon substrate 100 in medium-voltage device region 102 outside medium-voltage gate structure region; the second spacer material layer 110 remaining on the side surfaces of the low-voltage, medium-voltage and high-voltage gate structures forms sidewall spacers of the high-voltage and low-voltage gate structures, and results in medium-voltage gate structure having laterally stacked sidewall spacer composed of the first and second spacer material layers 110, wherein
in step S10, source/drain ion implantation is performed to form source/drain regions of the medium-voltage device, the high-voltage device, and the low-voltage device, wherein
the source/drain region of the low-voltage device is self-aligned with the sidewall spacers of the low-voltage gate structure, wherein
the source/drain region of the high-voltage device is self-aligned with the sidewall spacers of the high-voltage gate structure, and wherein
the source/drain region of the medium-voltage device is self-aligned with sidewall spacers of the medium-voltage gate structure.

Preferably, in step S1, high-voltage device region 101 is further divided by shallow trench isolation 104 into a central high-voltage gate structure region and lateral high-voltage ion implantation regions 200, N-type heavy ion implantation is performed in high-voltage ion implantation regions 200, wherein
in step S2, gate dielectric layers 105 are formed on the silicon substrate 100 in the high-voltage gate structure region of high-voltage device region 101 and in medium-voltage device region 102; top surfaces of the gate dielectric layers 105 are flush with top surface of shallow trench isolation 104, and the thickness of gate dielectric layer 105 in the high-voltage gate structure region is greater than that in the medium-voltage device region 102.

Preferably, the gate dielectric layer 105 is silicon oxide.

Preferably, the high-k dielectric layer 106 is HfO2 or HfSiON.

Preferably, the first mask layer 108 is a stacked structure of silicon nitride 1081 and silicon oxide 1082.

Preferably, the second spacer material layer 110 as well as the first spacer material layer 109 are made of different materials.

Preferably, the first spacer material layer 109 is silicon carbonitride or silicon nitride, wherein
the second spacer material layer 110 is silicon oxide.

Preferably, the second spacer material layer 110 is formed by a TEOS CVD process.

Preferably, in step S9, wet etching is performed using hydrofluoric acid to remove the second spacer material layer 110 outside side surfaces of medium-voltage gate structure and the high-voltage gate structure, thereby exposing top surface of the silicon substrate 100 in medium-voltage device region 102 outside medium-voltage gate structure region.

In high-voltage process for forming integrated structure of MOS device according to the present invention, after depositing the gate polysilicon layer and the first mask layer, a first gate mask is used to first define the medium-voltage gate structure region pattern (MV gate pattern). With the use of a dedicated mask, the medium-voltage gate structure undergoes a specialized etch to ensure that the gate dielectric layer 105 outside the medium-voltage gate structure region in the medium-voltage device region 102 is removed, thereby exposing the top surface of the silicon substrate 100. After deposition of the second spacer material layer 110, a blank etch is performed across the target regions to form standard sidewall spacers for the high-voltage gate structure, while simultaneously thickening the sidewall spacers of the medium-voltage gate structure. This eliminates requirement for a separate mask for sidewall spacer formation. Subsequently, a separate gate dielectric removal process (IOR process) for medium-voltage device formation region is no longer required, thereby saving a mask otherwise used for removing the gate dielectric layer in medium-voltage region. By adding only one additional gate mask of the first gate mask, the high-voltage process for forming integrated structure of the MOS device requires only one additional mask, first gate mask, thereby reducing two masks that are otherwise needed for the sidewall spacer formation and gate dielectric removal in medium-voltage device region. Consequently, when forming an integrated MOS device structure with the equivalent functionality using an existing high-voltage process, the mask count can be decreased, the process complexity can be simplified, and manufacturing costs can be lowered.

### BRIEF DESCRIPTION OF THE DRAWINGS

In order to more clearly illustrate the technical solution of the present invention, the following briefly introduces the drawings required for use in the present invention. Obviously, drawings described below are only some embodiments of present invention. For those skilled in the art, other drawings can be derived from these figures without requiring inventive effort.

FIG. 1 to 9 are the schematic cross-sectional views of a high-voltage process for an integrated structure of MOS device according to an embodiment of the present invention.

Among them:

100. Silicon substrate; 101. High-voltage device region; 102. Medium-voltage device region; 103. Low-voltage device region; 104. Shallow trench isolation; 105. Gate dielectric layer;
106. High-k dielectric layer; 107. Gate polysilicon layer; 108. First mask layer; 1081. Silicon nitride; 1082. Silicon oxide; 109. First spacer material layer; 110. Second spacer material layer; 200. High-voltage ion implantation region.

### DETAILED DESCRIPTION OF THE DISCLOSURE

The technical solutions of the embodiments of the present invention will be clearly and completely described below with reference to accompanying drawings of embodiments. It is apparent that the described embodiments are only part of the embodiments of the present invention, rather than all embodiments. Based on the embodiments disclosed in the present invention, all other embodiments obtained by those skilled in the art without inventive effort shall fall within the scope of the present invention.

In the present invention, the terms “first,” “second,” and similar expressions do not denote any sequence, quantity or importance, but are merely used to distinguish the different components. Terms such as “comprising” or “including” indicate that the elements or objects preceding these terms encompass elements or objects listed thereafter and their equivalents, without excluding other elements or objects. The terms like “connected” or “coupled” are not limited to physical or mechanical connections but may also include the electrical connections, whether direct or indirect. The terms such as “above”, “below”, “left”, “right”, “front” as well as “back” are used solely to indicate relative positional relationships. When absolute position of described object changes, relative positional relationships may also change accordingly.

It should be noted that, where no conflict occurs, features of the embodiments and embodiments themselves disclosed in present invention may be combined with each other.

### Embodiment 1

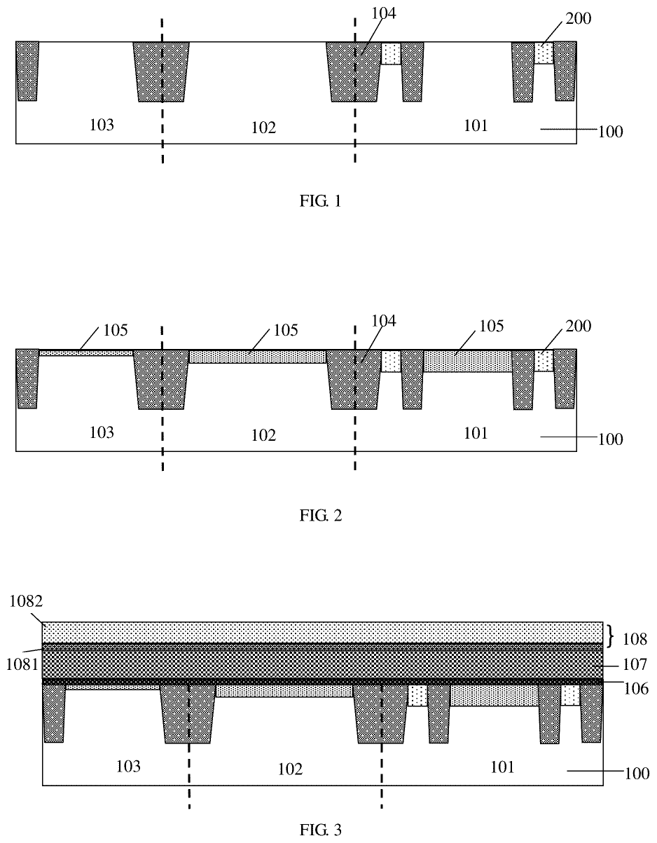

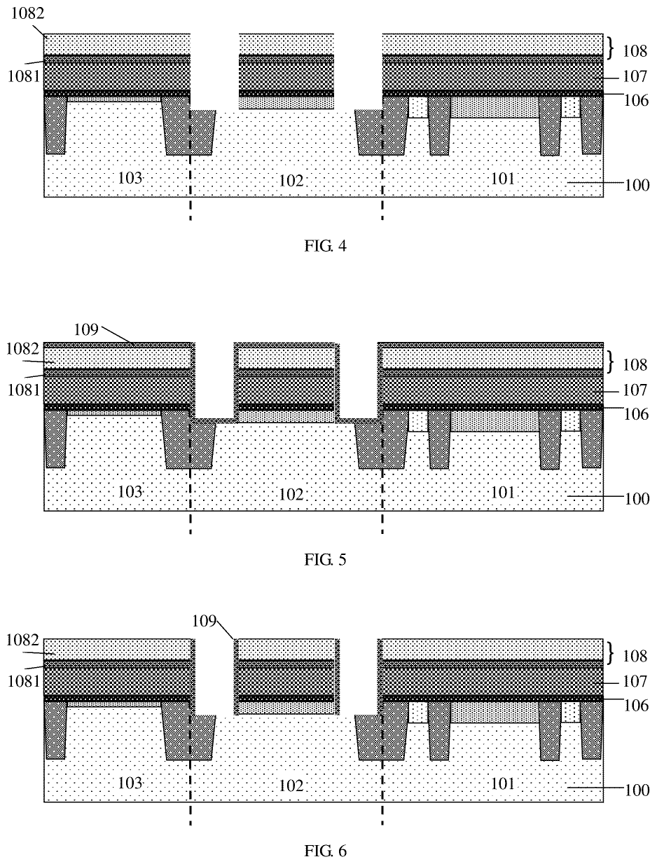

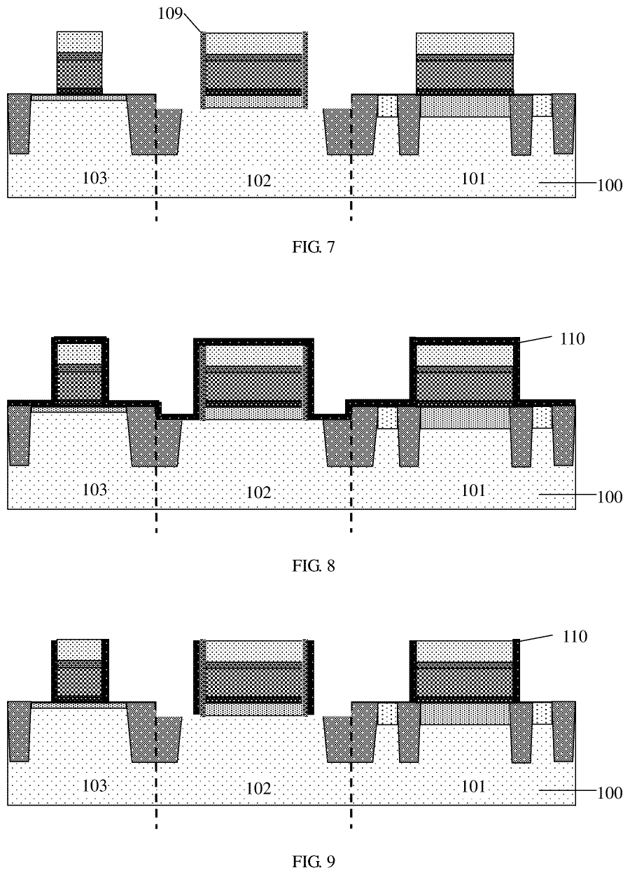

A high-voltage process for forming integrated structure of MOS device comprises the following steps:
S1: An active area (AA) process is performed on the silicon substrate 100, such that the silicon substrate 100 is divided into high-voltage device region 101 and medium-voltage device region 102 by shallow trench isolation (STI), as shown in FIG. 1;
S2: Gate dielectric layers 105 are respectively formed on the silicon substrate 100 in high-voltage device region 101 and medium-voltage device region 102. The top surfaces of the gate dielectric layers 105 are flush with the top surface of the shallow trench isolation 104. The thickness of the gate dielectric layer 105 in the high-voltage device region 101 is greater than that in the medium-voltage device region 102, as shown in FIG. 2;
S3: A high-k (HK) dielectric layer 106, a polysilicon gate layer 107, and a first mask layer 108 are sequentially formed on the gate dielectric layer 105, as shown in FIG. 3;
S4. A medium-voltage device gate structure region is defined in the medium-voltage device region 102 by using first gate mask, and the first mask layer 108, the gate polysilicon layer 107, the high-k dielectric layer 106 and the gate dielectric layer 105 of medium-voltage device region 102 outside the medium-voltage device gate structure region are removed by etching, and the etching is stopped at the top surface of the silicon substrate 100, exposing the top surface of silicon substrate 100 outside the medium-voltage device gate structure region of medium-voltage device region 102, and the gate dielectric layer 105, the high-k dielectric layer 106, the gate polysilicon layer 107 and the first mask layer 108 of the medium-voltage device gate structure region are retained to form a medium-voltage device gate structure, and gate dielectric layer 105, high dielectric constant dielectric layer 106, gate polysilicon layer 107 and the first mask layer 108 of the high-voltage device region 101 are retained, and then the photoresist is removed, as shown in FIG. 4;
S5: First spacer material layer 109 deposited, as shown in FIG. 5;
S6: Wet etching process (blank etch in the target region) is performed to retain only first spacer material layer 109 on sidewalls of the first mask layer 108, the gate polysilicon layer 107, the high-k dielectric layer 106 and the gate dielectric layer 105, while removing the first spacer material layer 109 elsewhere, thereby forming medium-voltage gate spacer (MV gate spacer), as shown in FIG. 6;
S7: The high-voltage device gate structure region is defined in high-voltage device region 101 by using the second gate mask, and the first mask layer 108, the gate polysilicon layer 107 and the high-k dielectric layer 106 of the high-voltage device region 101 outside the high-voltage device gate structure region are removed by etching, and the etching stops at the top surface of the gate dielectric layer 105, and the high-k dielectric layer 106, the gate polysilicon layer 107 and the first mask layer 108 sequentially stacked on the gate dielectric layer 105 in high-voltage device gate structure region are retained as the high-voltage device gate structure, and the medium-voltage device gate structure in the medium-voltage device gate structure region is retained, and then the photoresist is removed, as shown in FIG. 7;
S8: The second spacer material layer 110 is deposited, as shown in FIG. 8;
S9: Wet etching process (blank etch in the target region) is performed to remove the second spacer material layer 110 except on sidewalls of the medium-voltage gate structure and the high-voltage gate structure, thereby exposing top surface of the silicon substrate 100 outside the medium-voltage gate structure region in the medium-voltage device region 102. The second spacer material layer 110 is retained on the sidewalls of the medium-voltage and high-voltage gate structures, forming the high-voltage gate spacer. The medium-voltage gate spacer is composed of a lateral stack of the first spacer material layer and the second spacer material layer 110, as shown in FIG. 9.
S10: The subsequent processes are performed.

Preferably, the high-voltage process is a 28 HV (28 nm high voltage) process.

In high-voltage process for forming integrated structure of MOS device according to Embodiment 1, after the deposition of the gate polysilicon layer and the first mask layer, medium-voltage gate pattern (MV gate pattern) is first defined using a first gate mask. With a dedicated mask, the medium-voltage gate structure undergoes selective etching to ensure that the gate dielectric layer 105 in the medium-voltage device region 102 outside the medium-voltage gate structure region is removed, thereby exposing top surface of the silicon substrate 100. After the deposition of the second spacer material layer 109, a blank etch is performed in the target regions to form standard sidewall spacers for the high-voltage gate structure and to thicken sidewall spacers of medium-voltage device. This approach eliminates the need for one mask for sidewall spacer formation. Furthermore, since gate dielectric layer 105 does not cover silicon substrate at the source/drain (S/D) regions on both sides of medium-voltage gate structure, a separate gate dielectric removal process (IOR process) for medium-voltage device region is no longer required, thereby saving an additional mask for gate dielectric removal in that region.

In high-voltage process for forming integrated structure of MOS device described in Embodiment 1, only one additional gate mask (first gate mask) is required, which eliminates need for two other masks that would otherwise be used for sidewall spacer formation and for removing the gate dielectric layer in the medium-voltage device region. As a result, when forming the integrated structure of MOS device with similar functions by using existing high-voltage processes, this method can reduce the number of required masks, simplify the process flow, and lower manufacturing costs.

### Embodiment 2

Based on the high-voltage process for forming integrated structure of MOS device described in Embodiment 1, in Step S10, source/drain ion implantation is performed to form the source/drain regions of the medium-voltage device and the high-voltage device.

The source/drain regions of the high-voltage device are self-aligned with sidewall spacers of the high-voltage gate structure.

The source/drain regions of medium-voltage device are self-aligned with sidewall spacer of the medium-voltage gate structure.

### Embodiment 3

Based on the high-voltage process for forming integrated structure of MOS device in Embodiment 1, in step S1, the silicon substrate 100 is separated into high-voltage device region 101, medium-voltage device region 102 and low-voltage device region 103 by shallow trench isolation.

In step S2, gate dielectric layer 105 is also formed on the silicon substrate 100 in the medium-voltage device region 102. The top surfaces of respective gate dielectric layers 105 are flush with the top surface of the shallow trench isolation 104. The thickness of the gate dielectric layer 105 in high-voltage device region 101 is greater than that in medium-voltage device region 102, and the thickness of the gate dielectric layer 105 in the medium-voltage device region 102 is greater than that in the low-voltage device region 103.

In step S4, the sequentially stacked first mask layer 108, gate polysilicon layer 107, high-k dielectric layer 106, and gate dielectric layer 105 in the low-voltage device region 103 are retained.

In step S7, second gate mask is used to define high-voltage gate structure region in the high-voltage device region 101 and a low-voltage gate structure region in the low-voltage device region 103. The first mask layer 108, gate polysilicon layer 107 and high-k dielectric layer 106 in the high-voltage device region 101 outside the high-voltage gate structure region are etched and removed, stopping on the top surface of the gate dielectric layer 105. The first mask layer 108, gate polysilicon layer 107 and high-k dielectric layer 106 in the low-voltage device region 103 outside the low-voltage gate structure region are also etched and removed, stopping on top surface of gate dielectric layer 105. The remaining stacked layers of high-k dielectric layer 106, gate polysilicon layer 107 and first mask layer 108 over gate dielectric layer 105 in the high-voltage gate structure region and the low-voltage gate structure region are retained as high-voltage gate structure and low-voltage gate structure respectively. The gate structure in the medium-voltage gate structure region is also retained. The photoresist is then removed.

In step S9, wet etching process is performed to remove the second spacer material layer 110 from areas other than side surfaces of medium-voltage gate structure, low-voltage gate structure and high-voltage gate structure, thereby exposing the top surface of the silicon substrate 100 outside the medium-voltage gate structure region in the medium-voltage device region 102. The portions of the second spacer material layer 110 remaining on side surfaces of medium-voltage gate structure, low-voltage gate structure and high-voltage gate structure are retained, thereby forming the sidewall spacers of the high-voltage gate structure and the low-voltage gate structure. The sidewall spacers of the medium-voltage gate structure consist of a horizontally stacked first spacer material layer and the second spacer material layer 110.

In step S10, source/drain ion implantation is performed to form source/drain regions of the medium-voltage device, the high-voltage device and the low-voltage device.

The source/drain region of low-voltage device is self-aligned with the side surface of the sidewall spacer of the low-voltage gate structure.

The source/drain region of high-voltage device is self-aligned with the side surface of the sidewall spacer of the high-voltage gate structure.

The source/drain region of medium-voltage device is self-aligned with side surface of the sidewall spacer of the medium-voltage gate structure.

### Embodiment 4

Based on high-voltage process for forming the integrated structure of MOS device according to Embodiment 1, in step S1, the high-voltage device region 101 is further divided by the shallow trench isolation (STI) 104 into the central high-voltage gate structure region and the lateral high-voltage ion implantation regions 200. N-type heavy ion implantation is performed in the high-voltage ion implantation regions 200.

In step S2, the gate dielectric layer 105 is formed on the silicon substrate 100 in the high-voltage device gate structure region of the high-voltage device region 101 as well as the medium-voltage device region 102. The top surface of each gate dielectric layer 105 is flush with the top surface of shallow trench isolation 104, and the thickness of the gate dielectric layer 105 in the high-voltage device gate structure region is greater than the thickness of the gate dielectric layer 105 in the medium-voltage device region 102.

Preferably, the gate dielectric layer 105 is silicon oxide.

Preferably, the high-k (HK) dielectric layer 106 is HfO2 or HfSiON.

Preferably, the first mask layer 108 is a stacked structure of silicon nitride 1081 and silicon oxide 1082.

### Embodiment 5

In high-voltage process for forming integrated structure of MOS device according to Embodiment 1, the second spacer material layer 110 and the first spacer material layer 109 are made of different materials.

Preferably, first spacer material layer 109 is carbon-doped silicon nitride or silicon nitride

Preferably, the second spacer material layer 110 is silicon oxide.

Preferably, in step S8, TEOS CVD (chemical vapor deposition) process is used to deposit and form the second spacer material layer 110.

Preferably, in Step S9, wet etching is performed using hydrofluoric acid to remove the portions of the second spacer material layer 110 other than those on the side surfaces of medium-voltage gate structure and high-voltage gate structure, thereby exposing surface of silicon substrate 100 in areas of medium-voltage device region 102 outside medium-voltage gate structure region. The oxide layer serving as the second spacer material layer 110 is also referred to as a TEOS oxide layer. Compared with silicon carbonitride, the TEOS oxide layer exhibits a very high etch selectivity in hydrofluoric acid. The etch rate ratio of TEOS oxide layer to silicon carbonitride exceeds 30:1.

The above description is only some preferred embodiments of the present invention and is not intended to limit protection scope of present invention. Any modifications, equivalent substitutions, improvements, etc. made within spirit as well as principles of present invention should be included in the scope of protection of the present invention.

What is claimed is:

1. A high-voltage process for forming an integrated structure of a MOS device, comprising:
S1: performing an active region process on a silicon substrate, such that the silicon substrate is divided by shallow trench isolation into a high-voltage device region as well as a medium-voltage device region;
S2: forming gate dielectric layers on the silicon substrate in the high-voltage device region as well as the medium-voltage device region, wherein top surfaces of the gate dielectric layers are flush with a top surface of the shallow trench isolation, and a gate dielectric layer in the high-voltage device region is thicker than a gate dielectric layer in the medium-voltage device region;
S3: sequentially forming a high-k dielectric layer, a gate polysilicon layer, and a first mask layer over the gate dielectric layers;
S4: defining a medium-voltage gate structure region in the medium-voltage device region using a first gate mask, and etching away portions of the first mask layer, the gate polysilicon layer, the high-k dielectric layer, and the gate dielectric layer located outside the medium-voltage gate structure region, stopping at a top surface of the silicon substrate, thereby exposing a top surface of silicon substrate outside the medium-voltage gate structure region, retaining a stack within the medium-voltage gate structure region comprising the gate dielectric layer, the high-k dielectric layer, the gate polysilicon layer, and the first mask layer in sequence, which together form a medium-voltage gate structure, while retaining a stack of the gate dielectric layer, the high-k dielectric layer, the gate polysilicon layer, and the first mask layer in sequence in the high-voltage device region, and removing photoresist thereafter;
S5: depositing a first spacer material layer;
S6: performing wet etching to retain first spacer material layer only on side surfaces of the stack comprising the first mask layer, the gate polysilicon layer, the high-k dielectric layer, and the gate dielectric layer, and removing the rest, thereby forming a sidewall spacer of the medium-voltage gate structure;
S7: defining a high-voltage gate structure region in the high-voltage device region using a second gate mask, and etching away portions of the first mask layer, the gate polysilicon layer, and the high-k dielectric layer in the high-voltage device region outside high-voltage gate structure region, stopping at a top surface of the gate dielectric layer, retaining the stack within the high-voltage gate structure region comprising the high-k dielectric layer, the gate polysilicon layer, and the first mask layer in sequence over the gate dielectric layer to form a high-voltage gate structure, while retaining the medium-voltage gate structure in the medium-voltage gate structure region, and removing the photoresist thereafter;
S8: depositing a second spacer material layer;
S9: performing wet etching to remove second spacer material layer outside portions on side surfaces of the medium-voltage gate structure and the high-voltage gate structure, thereby exposing top surface of the silicon substrate outside the medium-voltage gate structure region in the medium-voltage device region, retaining the portions of the second spacer material layer on the side surfaces of the medium-voltage gate structure and the high-voltage gate structure forming sidewall spacers of the high-voltage gate structure, and making sidewall spacers of the medium-voltage gate structure the first spacer material layer as well as the second spacer material layer stacked laterally; and
S10: performing subsequent processes.

2. The high-voltage process for forming the integrated structure of the MOS device according to claim 1, wherein step S10 comprises performing source/drain ion implantation to form a source/drain region of a medium-voltage device and a source/drain region of a high-voltage device, wherein the source/drain region of the high-voltage device is self-aligned with sidewall spacers of the high-voltage gate structure, and wherein the source/drain region of the medium-voltage device is self-aligned with sidewall spacers of the medium-voltage gate structure.

3. The high-voltage process for forming the integrated structure of the MOS device according to claim 2, wherein,
in step S2, the gate dielectric layer is further formed on the silicon substrate in the medium-voltage device region, and each gate dielectric layer has a top surface that is flush with the top surface of the shallow trench isolation, a thickness of the gate dielectric layer in the high-voltage device region is greater than that in the medium-voltage device region, and a thickness of the gate dielectric layer in the medium-voltage device region is greater than that in a low-voltage device region, wherein,
in step S4, the sequentially stacked first mask layer, gate polysilicon gate layer, the high-k dielectric layer, and the gate dielectric layer in the low-voltage device region are retained, wherein,
in step S7, the second gate mask is used to define the high-voltage gate structure region in the high-voltage device region and the low-voltage gate structure region in the low-voltage device region, etching is performed to remove the first mask layer, the gate polysilicon layer, and the high-k dielectric layer in the high-voltage device region outside the high-voltage gate structure region, stopping at the top surface of the gate dielectric layer, etching is also performed to remove the first mask layer, the gate polysilicon layer, and the high-k dielectric layer in the low-voltage device region outside the low-voltage gate structure region, stopping at the top surface of the gate dielectric layer, wherein the high-k dielectric layer, the gate polysilicon layer, and first mask layer sequentially stacked on the gate dielectric layer in the high-voltage gate structure region as well as the low-voltage gate structure region are retained as the high-voltage gate structure and the low-voltage gate structure respectively, the medium-voltage gate structure in the medium-voltage gate structure region is also retained, and the photoresist is removed thereafter, wherein,
in step S9, wet etching is performed to remove the second spacer material layer outside the side surfaces of the medium-voltage gate structure, the low-voltage gate structure, and the high-voltage gate structure, thereby exposing the top surface of the silicon substrate in the medium-voltage device region outside the medium-voltage gate structure region, the second spacer material layer remaining on the side surfaces of low-voltage, medium-voltage, and high-voltage gate structures forms the sidewall spacers of the high-voltage gate structures and the low-voltage gate structures, and results in the medium-voltage gate structure having laterally stacked sidewall spacers composed of the first and second spacer material layers, wherein,
in step S10, source/drain ion implantation is performed to form source/drain regions of the medium-voltage device, the high-voltage device, and a low-voltage device, wherein
the source/drain region of the low-voltage device is self-aligned with sidewall spacers of the low-voltage gate structure, wherein
the source/drain region of the high-voltage device is self-aligned with sidewall spacers of the high-voltage gate structure, and wherein
the source/drain region of the medium-voltage device is self-aligned with the sidewall spacers of the medium-voltage gate structure.

4. The high-voltage process for forming the integrated structure of the MOS device according to claim 1, wherein,
in step S1, the high-voltage device region is further divided by shallow trench isolation into a central high-voltage gate structure region as well as lateral high-voltage ion implantation regions, N-type heavy ion implantation is performed in high-voltage ion implantation regions, and wherein,
in step S2, the gate dielectric layers are formed on the silicon substrate in the high-voltage gate structure region of the high-voltage device region and in the medium-voltage device region, top surfaces of the gate dielectric layers are flush with the top surface of shallow trench isolation, and a thickness of the gate dielectric layer in the high-voltage gate structure region is greater than that in the medium-voltage device region.

5. The high-voltage process for forming the integrated structure of the MOS device according to claim 1, wherein the gate dielectric layer is silicon oxide.

6. The high-voltage process for forming the integrated structure of the MOS device according to claim 1, wherein the high-k dielectric layer is HfO2 or HfSiON.

7. The high-voltage process for forming the integrated structure of the MOS device according to claim 1, wherein the first mask layer is a stacked structure of silicon nitride and silicon oxide.

8. The high-voltage process for forming the integrated structure of the MOS device according to claim 1, wherein the second spacer material layer and the first spacer material layer are made of different materials.

9. The high-voltage process for forming the integrated structure of the MOS device according to claim 8, wherein the first spacer material layer is silicon carbonitride or silicon nitride, and wherein the second spacer material layer is silicon oxide.

10. The high-voltage process for forming the integrated structure of the MOS device according to claim 9, wherein the second spacer material layer is formed by a TEOS CVD process.

11. The high-voltage process for forming the integrated structure of the MOS device according to claim 10, wherein, in step S9, wet etching is performed using hydrofluoric acid to remove the second spacer material layer outside the side surfaces of medium-voltage gate structure and high-voltage gate structure, thereby exposing a top surface of the silicon substrate in the medium-voltage device region outside the medium-voltage gate structure region.
